(19) United States
(12) Patent Application Publication
(10) Pub. No.: US 2026/0066246 A1
(43) Pub. Date: Mar. 5, 2026

(54) THIN-FILM ULTRA-HIGH FREQUENCY DIAGNOSTIC DEVICE FOR PLASMA DIAGNOSIS AND PLASMA DIAGNOSTIC MODULE COMPRISING SAME

(71) Applicant: KOREA INSTITUTE OF MACHINERY & MATERIALS, Daejeon (KR)

(72) Inventors: Dae-Woong KIM, Seoul (KR); Woo Seok KANG, Daejeon (KR); Min HUR, Daejeon (KR); Jinyeong LEE, Daejeon (KR); Hyeong U KIM, Daejeon (KR); Muyoung KIM, Daejeon (KR)

(21) Appl. No.: 18/879,113

(22) PCT Filed: Jul. 19, 2023
(86) PCT No.: PCT/KR2023/010354

§ 371 Date: Oct. 22, 2025

(30) Foreign Application Priority Data
Jul. 25, 2022 (KR) 10-2022-0091723
Mar. 7, 2023 (KR) 10-2023-0030089

(51) Int. Cl. H01J 37/32

(52) U.S. Cl. CPC H01J 37/32917

(57) ABSTRACT

In a thin-film ultra-high frequency diagnostic device for plasma diagnostics and a plasma diagnostic module comprising the same, the ultra-high frequency diagnostic device comprises at least one antenna located in a space where plasma is generated, and the antenna comprises a base substrate and an electrode unit formed on the base substrate along a center of the base substrate and exposed to the space where the plasma is generated to transmit and receive an ultra-high frequency signal.

### TECHNICAL FIELD

The present invention relates to a thin-film ultra-high frequency diagnostic device and a plasma diagnostic module comprising the same, and more specifically, to a diagnostic device for diagnosing plasma and to a plasma diagnostic module comprising the same. The diagnostic device is located or attached in a space where plasma is generated to diagnose plasma. The device is formed in a thin-film type so that it is easily manufacturable and capable of accurately and effectively diagnosing plasma in various usage environments.

### BACKGROUND

In manufacturing processes of semiconductor devices, etching or deposition processes using vacuum plasma are applied. As semiconductor devices become more refined and as their structures become more complex, precise control of the plasma is required.

For precise control of the plasma, more accurate measurement of the plasma generated inside a process equipment is necessary.

In this regard, Korean Patent No. 10-2323995 discloses a technology related to a plasma diagnostic device that is embedded in a wall of a chamber to diagnose the plasma within the chamber.

Additionally, Korean Patent Publication No. 10-2020-0095022 discloses a technology related to a plasma diagnostic device with a block shape or a non-flexible plate shape, which is also embedded in the wall of the chamber as described above.

As described above, technologies related to diagnostic devices for plasma diagnosis have been developed. However, until now, these devices are manufactured in an embedded form within structures such as chambers, requiring the diagnostic device to be manufactured simultaneously during the chamber's production process. Once manufactured or embedded, position or structure of the diagnostic device cannot be changed.

Furthermore, as diagnostic devices are developed as rigid structures, such as block shapes or plate shapes, rather than flexible structures, they may only be attached to flat surfaces or require separate fixing units to be attached to pre-formed structures. Thus, there are limitations regarding attachment and detachment of the diagnostic device.

Additionally, plasma diagnostic devices are provided on one side or outside of the chamber rather than in the chamber, making it difficult to accurately diagnose the plasma generated at the center of the chamber.

Moreover, as diagnostic devices are developed as rigid structures, such as block shapes or plate shapes, rather than flexible structures, they may only be attached to flat surfaces or require separate fixing units to be attached to pre-formed structures. Thus, there are limitations regarding attachment and detachment of the diagnostic device.

Related prior art documents include Korean Patent No. 10-2323995 and Korean Patent Publication No. 10-2020-0095022.

### DETAILED DESCRIPTION OF THE INVENTION

### Technical Problem to be Solved

The technical problem of the present invention is conceived in view of the above points, and an object of the present invention is to provide a thin-film ultra-high frequency diagnostic device for plasma diagnosis, which is formed in a thin-film type so that it is easily manufacturable, and capable of accurately and effectively diagnosing plasma in various usage environments by being arranged or attached in a space where plasma is generated.

Another object of the present invention is to provide a plasma diagnostic module comprising the ultra-high frequency diagnostic device.

### Means for Solving Problem

An ultra-high frequency diagnostic device according to an embodiment of the present invention comprises at least one antenna located in a space where plasma is generated, and the antenna includes a base substrate and an electrode unit formed on the base substrate along a center of the base substrate and exposed to the space where the plasma is generated to transmit and receive an ultra-high frequency signal.

In an embodiment, the base substrate is a flexible dielectric substrate, and the electrode unit may be formed of a flexible metal thin-film.

In an embodiment, the electrode unit may include a signal processing part, a signal line transmitting and receiving the ultra-high frequency signal, and a transceiving portion formed at an end of the signal line and transmitting or receiving the ultra-high frequency signal.

In an embodiment, the transceiving portion may be formed of one of a circular thin film, a semicircular thin film, a mesh-shaped circular thin film, a triangular thin film, a rectangular thin film, and a polygonal thin film.

In an embodiment, the transceiving portion may have a lower surface formed as a thin film and be formed to protrude in a hemispherical shape on the lower surface.

In an embodiment, the at least one antenna includes first and second antennas, and a transceiving portion of the second antenna may be arranged to cover an outside of a transceiving portion of the first antenna.

In an embodiment, the at least one antenna includes two antennas, one of the two antennas transmits the ultra-high frequency signal, and the other receives the ultra-high frequency signal, and as a distance between the two antennas varies, plasma information according to a depth direction of the plasma may be acquired.

In an embodiment, the antennas include three or more antennas, the three or more antennas transmit and receive the ultra-high frequency signal between each other, and plasma information according to a depth direction of the plasma may be acquired according to a distance between the three or more antennas.

In an embodiment, the antenna may further include a ground portion formed on the lower surface of the base substrate along a center of a lower surface of the base substrate.

In an embodiment, an end of the antenna is fixed to a structure forming the space where the plasma is generated, or a lower surface of the antenna is attached to a surface of the structure.

In an embodiment, a transparent viewing window is formed in the space where the plasma is generated, and the antenna may be exposed to the space where the plasma is generated through the transparent viewing window.

An ultra-high frequency diagnostic device according to one embodiment of the present invention comprises a base substrate and an electrode unit formed on the base substrate. In this case, the electrode unit includes a signal line portion and a ground line. The signal line portion includes a transceiving portion exposed to a space where plasma is generated and detecting an ultra-high frequency signal, and a signal line extending from the transceiving portion to deliver a detection signal to an outside, and the ground line is formed on the same surface of the base substrate on which the signal line portion is formed, spaced apart from the signal line portion, and extending along an extension direction of the signal line portion.

In an embodiment, the base substrate is a wafer or a panel, and the electrode unit may be directly formed on the base substrate as a flexible metal thin film.

In an embodiment, the transceiving portion, the signal line portion, and the ground line of the electrode unit may be simultaneously formed on the base substrate.

In an embodiment, the base substrate may have one of a circular plate shape, a plate shape extending in a longitudinal direction, a rectangular plate shape, a polygonal plate shape, and a curved surface shape.

In an embodiment, the transceiving portion may be formed such that a width thereof increases as a distance from the signal line portion increases.

In an embodiment, the electrode unit may further include a ground portion formed on a surface opposite to the surface of the base substrate on which the signal line portion is formed.

An ultra-high frequency diagnostic device according to one embodiment of the present invention comprises a signal line portion, a dielectric portion, and a ground portion. The signal line portion includes a transceiving portion exposed to a space where plasma is generated and detecting an ultra-high frequency signal, and a signal line extending from the transceiving portion to deliver a detection signal to an outside. The dielectric portion has the signal line portion formed on a lower surface thereof and has an opening formed such that the transceiving portion is exposed to the space where the plasma is generated. The ground portion is formed on an upper surface of the dielectric portion along an area where the signal line is formed.

In an embodiment, the signal line portion and the ground portion may be formed of a flexible metal thin-film.

In an embodiment, the signal line extends in a longitudinal direction along the lower surface of the dielectric portion, and the ground portion may be formed on an entire upper surface of the dielectric portion.

### Effects of the Invention

According to the embodiments of the present invention as described above, unlike conventional embedded or integrated ultra-high frequency diagnostic devices, the ultra-high frequency diagnostic device may be located in a space where plasma is generated to measure the plasma. Thus, it may be located at any position in various spaces where plasma is generated, thereby enabling effective plasma measurement without structural design for embedding the diagnostic device.

In this case, since the antenna is formed of a flexible metal thin film, it is not only easy to manufacture but also may be easily attached and detached to an inner surface of structures with various shapes. Additionally, an end of the antenna may be fixed to the structure, thereby allowing it to remain in the space, thereby improving convenience in installation and removal.

In addition, a transceiving portion constituting the antenna may be formed in various shapes, not only in a planar shape but also in a three-dimensional shape such as a hemispherical shape thereby allowing control of the signal strength, and may be manufactured in an optimal shape considering various plasma generation or measurement environments.

In addition, plasma monitoring may be conducted by using a single antenna to perform both transmission and reception simultaneously. Additionally, by changing a distance between two antennas, a depth of the measured plasma may be variably controlled. Furthermore, by arranging three or more antennas at once, plasma may be measured at various depths through signal transmission and reception between the antennas, thereby obtaining information about plasma state in a three-dimensional space.

In this case, if damage to the ultra-high frequency diagnostic device is anticipated due to the plasma, the plasma generation space and the diagnostic device may be opened through a transparent viewing window that allows passage of ultra-high frequency, thereby minimizing damage to the diagnostic device while enabling plasma diagnosis.

In particular, the ultra-high frequency diagnostic device may be arranged in multiple units to form a plasma diagnostic module. This plasma diagnostic module may be located in the space where plasma is generated, such as a chamber, or attached to an inner surface of the chamber in a predetermined pattern. This allows acquisition of three-dimensional information about plasma generation state, by enabling more accurate and detailed information acquisition about plasma generation state.

Furthermore, the plasma diagnostic module may be attached to a wafer chuck, thereby allowing precise monitoring of plasma state around the wafer when a plasma process for semiconductor wafers is performed.

Meanwhile, the diagnostic device has an electrode unit formed only on one surface of a dielectric base substrate, thereby simplifying the manufacturing process of the electrode unit and enabling mass production.

Additionally, the base substrate may be manufactured in various shapes, such as a circular plate shape like a wafer, or a longitudinal plate shape. It may be made of a dielectric thin film, thereby allowing it to be easily positioned in a detachable form at the location where plasma measurement is needed, thereby improving convenience in installation and removal.

Furthermore, structures such as wafers or display panels may be used for the base substrate, thereby allowing easy plasma measurement by simply attaching and detaching the electrode unit.

Alternatively, in the electrode unit, by removing a ground portion at the portion where the transceiving portion detecting the plasma is formed, such that the transceiving portion is formed to be exposed to an outside through an opening, the coupling efficiency of the ultra-high frequency signal to the plasma may be further improved, thereby enabling more accurate signal measurement.

Moreover, by forming the electrode unit in pairs or more, a signal passing through the plasma may be measured through signal transmission and reception, thereby allowing the measurement of plasma at various depths and obtaining information about plasma state in a three-dimensional space.

### BRIEF DESCRIPTION OF THE DRAWINGS

FIG. 1 is a schematic diagram showing a thin-film ultra-high frequency diagnostic device according to an embodiment of the present invention.

FIGS. 2a and 2b are graphs showing the change in transmittance when plasma is measured through the ultra-high frequency diagnostic device of FIG. 1.

FIG. 3 is a schematic diagram showing a thin-film ultra-high frequency diagnostic device according to another embodiment of the present invention.

FIG. 4 is a schematic diagram showing a thin-film ultra-high frequency diagnostic device according to another embodiment of the present invention.

FIGS. 5a to 5e are schematic diagrams showing examples of shapes of transceiving portions and end portions in the ultra-high frequency diagnostic devices of FIGS. 1, 3, and 4.

FIG. 6 is a perspective view showing a state in which a plasma diagnostic module including the ultra-high frequency diagnostic devices of FIGS. 1, 3, and 4 is attached to a chamber part.

FIG. 7 is a perspective view showing a state in which a plasma diagnostic module including the ultra-high frequency diagnostic devices of FIGS. 1, 3, and 4 is attached to a wafer chuck.

FIG. 8 is a perspective view showing a state in which a plasma diagnostic module including the ultra-high frequency diagnostic device of FIG. 1 is attached to a viewing window of the chamber part.

FIG. 9 is a plan view showing a thin-film ultra-high frequency diagnostic device according to another embodiment of the present invention.

FIG. 10a is an embodiment of a cross-sectional view taken along line I-I′ of FIG. 9, and FIG. 10b is another embodiment of a cross-sectional view taken along line I-I′ of FIG. 9.

FIG. 11 is a plan view showing another embodiment of the thin-film ultra-high frequency diagnostic device according to the present invention.

FIG. 12a is an enlarged plan view showing a pair of electrode units in the ultra-high frequency diagnostic device of FIG. 11, FIG. 12b is a cross-sectional view taken along line II-II′ of FIG. 12a, and FIG. 12c is a cross-sectional view taken along line III-III′ of FIG. 12a.

FIG. 13 is a plan view showing a thin-film ultra-high frequency diagnostic device according to another embodiment of the present invention.

FIG. 14 is a plan view showing a thin-film ultra-high frequency diagnostic device according to another embodiment of the present invention.

FIG. 15a is a plan view showing an electrode unit of a thin-film ultra-high frequency diagnostic device according to another embodiment of the present invention, FIG. 15b is a cross-sectional view taken along line IV-IV′ of FIG. 15a, and FIG. 15c is a cross-sectional view taken along line V-V′ of FIG. 15a.

FIG. 16a is a graph showing a transmission spectrum of a diagnostic result using a conventional ultra-high frequency diagnostic device, and FIG. 16b is a graph showing a transmission spectrum of a diagnostic result using the ultra-high frequency diagnostic device of FIG. 15a.

<reference numerals>

| | |
|---|---|
| 10, 20, 30, 40, 50, 60, 70, 80: ultra- | |
| high frequency diagnostic devices | |
| 11, 21, 31: plasma diagnostic modules | |
| 100, 101, 200, 201, 300, 400: antennas | |
| 110, 130, 210, 230, 1200, 1201, 1300, | |
| 1400, 1401: electrode units | |
| 1210, 1410: signal line portions | 1220: ground line |
| 1230, 1430: ground portions | 1250: connection wiring |
| 120, 220, 1100, 1102, 1102: base | |
| substrate | |
| 1440: dielectric portion | 1441: opening |
| 111, 131, 211, 231, 311, 411, 1212, | |
| 1412: signal lines | |
| 112, 132, 212, 232, 312, 412, 1211, | |
| 1411: transceiving portions | |
| 190, 290: ends | 191, 291: lower surfaces |
| 600: signal processing part | 610, 620: signal transmission |
| | lines |
| 611, 612, 621, 622, 623, 624: transmission | |
| lines | |
| 700: chamber part | 800: transparent viewing |
| | window |

### BEST EMBODIMENT FOR IMPLEMENTING THE INVENTION

The present invention may undergo various modifications and may have various forms, and thus, embodiments will be described in detail in the text. However, this is not intended to limit the invention to specific disclosed forms, and it should be understood to include all modifications, equivalents, and substitutes included within the spirit and scope of the invention. Similar reference numerals have been used for similar components while describing each drawing. Terms such as first and second may be used to describe various components, but these components should not be limited by these terms.

The terms are only used to distinguish one component from another. The terms used in this application are only used to describe specific embodiments and are not intended to limit the invention. Singular expressions include plural expressions unless the context clearly indicates otherwise.

In this application, terms such as “comprising” or “consisting of” are intended to specify the presence of stated features, numbers, steps, operations, components, parts, or combinations thereof, but do not preclude the possibility of the presence or addition of one or more other features, numbers, steps, operations, components, parts, or combinations thereof.

Unless otherwise defined, all terms used herein, including technical or scientific terms, have the same meaning as commonly understood by one of ordinary skill in the art to which this invention belongs. Terms defined in commonly used dictionaries should be interpreted as having meanings consistent with the context of the relevant art and should not be interpreted in an idealized or overly formal sense unless expressly defined in this application.

Hereinafter, preferred embodiments of the present invention will be described in more detail with reference to the accompanying drawings.

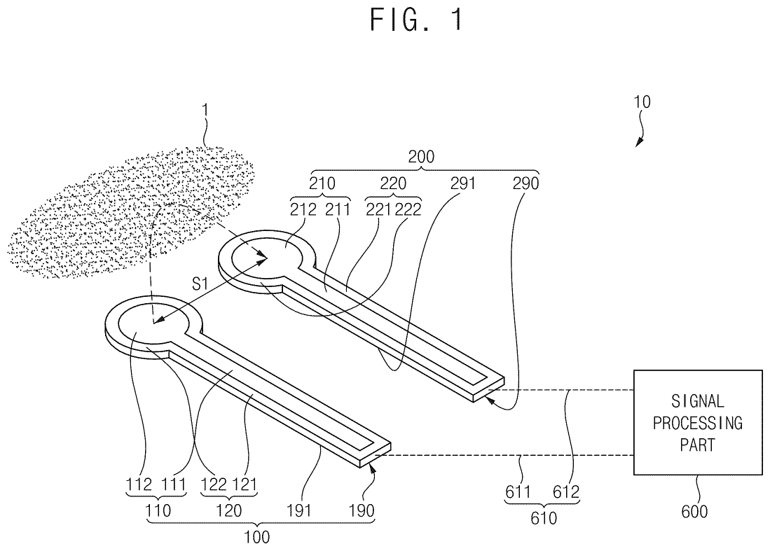

FIG. 1 is a schematic diagram showing a thin-film ultra-high frequency diagnostic device according to an embodiment of the present invention.

Referring to FIG. 1, a thin-film ultra-high frequency diagnostic device (hereinafter referred to as an ultra-high frequency diagnostic device) 10 according to this embodiment includes a pair of first and second antennas 100 and 200 and a signal processing part 600.

First, the first antenna 100 may be located in a space where plasma 1 is generated and includes a first electrode unit 110 and a first base substrate 120. Meanwhile, although not shown, the first antenna 100 may further include a first ground portion. In this case, as will be described later, the first electrode unit 110 and the first ground portion are each formed in a thin-film shape on upper and lower surfaces of the first base substrate 120.

Even though FIG. 1 shows that the plasma 1 is generated is shown without defining an individual space, but the plasma 1 and the first and second antennas 100 and 200 shown in FIG. 1 may be located inside a specific space.

The first electrode unit 110 includes a first signal line 111 extending in a direction and a first transceiving portion 112 formed at an end of the first signal line 111, which faces the space where the plasma 1 is generated.

In this case, the first signal line 111 extends in the longitudinal direction with a predetermined width, and the extension length in the longitudinal direction of the first signal line 111 may be relatively much larger than the width.

Also, the first signal line 111 is formed of a relatively thin film.

The first transceiving portion 112 may have a circular shape as shown, and the area of the circular shape may be variously designed. Also, the first transceiving portion 112 is formed of a relatively thin film, similar to the first signal line 111.

That is, the first electrode unit 110 is formed of a thin film and may have flexible properties. Similarly, the first base substrate 120 may also have flexible properties.

Thus, the first antenna 100 may be located at any position in the space where the plasma 1 is generated. However, even if the first electrode unit 110 is located at any position in the space where the plasma 1 is generated, an end 190 of the first antenna 100 may be fixed to a surface of a structure (not shown) forming the space.

Alternatively, the first antenna 100 may be attached to a surface of a structure (not shown) forming the space by an adhesive material formed on the lower surface 191. In this case, since both the first electrode unit 110 and the first base substrate 120 have flexibility, they may be stably attached regardless of whether the surface of the structure is curved.

The first electrode unit 110 includes a metal such as copper, and thus, an electric signal may be transmitted, which will be described later.

As described above, the first electrode unit 110, including the first signal line 111 and the first transceiving portion 112, may be formed in a thin-film shape on the upper surface of the first base substrate 120. In this case, the method or process of forming the first electrode unit 110 on the upper surface of the first base substrate 120 may include various processes such as coating, deposition, attachment, and adhesion, and is not limited thereto. That is, conventional processes for forming metal thin films may be used for forming the first electrode unit 110, and since those are well-known technologies, detailed description thereof is omitted.

Meanwhile, although the first base substrate 120 is integrally formed as a base substrate as shown in FIG. 1, for convenience of explanation, the first base substrate 120 is described as including a first extended dielectric 121 and a first end portion 122.

The first base substrate 120 may include polyimide (PI) and may be a dielectric. Thus, it may generate a predetermined electrical induction effect on an electrical signal transmitted through the first electrode unit 110.

The first extended dielectric 121 extends along an edge of the first signal line 111 and is exposed along the edge of the first signal line 111. That is, since the first signal line 111 is formed along a center of the first extended dielectric 121, the first extended dielectric 121 is naturally exposed only to an edge side of the first signal line 111.

In this case, the first extended dielectric 121 is exposed to an outside along both edges of the first signal line 111 extending in the longitudinal direction, and the length of the first extended dielectric 121 may be substantially the same as the length of the first signal line 111. However, the width of the portion of the first extended dielectric 121, which is exposed to the outside, may be formed smaller than the width of the first signal line 111.

The first end portion 122 is also exposed to the outside along the edge of the first transceiving portion 112. That is, since the first transceiving portion 112 is formed at the center of the first end portion 122, the first end portion 122 is naturally exposed only to the edge side of the first transceiving portion 112.

In this case, if the first end portion 122 has a circular shape, the first transceiving portion 112 may be formed in a circular shape with a smaller area than the area of the first end portion 122. Thus, an edge portion of the first end portion 122 is also exposed to the outside.

Meanwhile, as described above, the lower surface 191 of the first antenna 100 may be attached to a surface of the structure.

Also, although not shown, a first ground portion may be formed on the lower surface 191 of the first antenna 100, that is, the lower surface of the first base substrate 120. In this case, the first ground portion performs grounding for the signal.

The first ground portion may be formed on the lower surface of the first base substrate 120 with the same shape as the first electrode unit 110. Of course, the shape of the first ground portion does not necessarily have to be identical to the first electrode unit 110 and may be formed with a smaller area than the lower surface of the first base substrate 120.

Thus, the lower surface of the first base substrate 120 may be also exposed to the outside except for the area where the first ground portion is formed.

Additionally, the first ground portion may be also formed of the same metal thin film as the first electrode unit 110, and the method or process of formation is not limited.

The second antenna 200 has substantially the same structure as the first antenna 100 and is arranged to be spaced apart from the first antenna 100 by a predetermined spacing distance.

The second antenna 200 is also located in the space where the plasma 1 is generated and should be arranged in pairs with the first antenna 100.

In this case, the second antenna 200 includes a second electrode unit 210 and a second base substrate 220, the second electrode unit 210 includes a second signal line 211 and a second transceiving portion 212, and the second base substrate 220 includes a second extended dielectric 221 and a second end portion 222.

Meanwhile, the second signal line 211, the second transceiving portion 212, the second extended dielectric 221, and the second end portion 222 are substantially the same in structure, shape, and arrangement as the first signal line 111, the first transceiving portion 112, the first extended dielectric 112, and the first end portion 121, so the previous description is referred to, and redundant explanations are omitted.

Furthermore, as described above, the first electrode unit 110 and the second electrode unit 210 are formed of thin films on the upper surfaces of the first base substrate 120 and the second base substrate 220, respectively, and although not shown, the ground portion is also formed as a thin film on the lower surfaces of the first base substrate 120 and the second base substrate 220.

In this case, since the first base substrate 120 and the second base substrate 220 are also formed with a thin thickness like a thin film, the first antenna 100 and the second antenna 200 are entirely formed as thin films or thin film substrates.

The signal processing part 600 includes a signal transmission line 610, transmits and receives electrical signals with the first and second antennas 100 and 200, processes the received to obtain information about the plasma 1.

In this case, the signal transmission line 610 includes a first transmission line 611 connecting the signal processing part 600 and the end 190 of the first antenna 100, and a second transmission line 612 connecting the signal processing part 600 and the end 290 of the second antenna 200.

The first and second antennas 100 and 200 in this embodiment may each transmit and receive electrical signals, and one of the antennas is not limited to a transmitting antenna while the other is a receiving antenna. Accordingly, one of the first transmission line 611 and the second transmission line 612 is not limited to a transmitting line while the other is a receiving line. However, hereinafter, for convenience of explanation, it will be explained that an electrical signal is transmitted through the first transmission line 611 and received through the second transmission line 612.

That is, the electrical signal generated through the signal processing part 600, i.e., the ultra-high frequency signal, is transmitted to the first signal line 111 through the first transmission line 611 and provided to the first transceiving portion 112 along the first signal line 112.

Thus, the ultra-high frequency signal generated from the first transceiving portion 112 passes through the plasma 1 and is received by the second transceiving portion 212, and the ultra-high frequency signal that has passed through the plasma 1 is transmitted to the second transmission line 612 through the second signal line 211 and finally received by the signal processing part 600.

Thus, the signal processing part 600 performs an analysis for state of the plasma 1 based on the received ultra-high frequency signal.

In this case, the ultra-high frequency signal may have a frequency band in the kHz to GHz range.

Meanwhile, although it has been explained that an individual signal transmission line 610 is connected by wire to transmit or receive the ultra-high frequency, the transmission and reception of the ultra-high frequency may be also performed wirelessly.

Furthermore, the signal processing part 600 is located outside the space where the plasma 6 is generated, and the signal transmission line 610 may be connected from the outside to the space where the plasma 1 is generated.

For example, if the ends 190 and 290 of the antennas 100 and 200 are fixed to a structure, the signal transmission line 610 may be connected from the outside to the ends 190 and 290 fixed to the structure. Alternatively, if the antennas 100 and 200 are attached to the surface of the structure, the signal transmission line 610 may be formed to be electrically connected to the signal lines 111 and 211 of the attached antennas 100 and 200 from the outside.

That is, the signal transmission line 610 may be electrically connected to the antennas 100 and 200 through an individual connection port (not shown).

Meanwhile, referring to FIG. 1, it is explained that a pair of first and second antennas 100 and 200 are arranged to be spaced apart from each other by a predetermined spacing distance, with one antenna transmitting the ultra-high frequency and the other receiving the ultra-high frequency.

However, although not shown, only one of the first and second antennas 100 and 200 may be arranged to simultaneously perform transmission and reception of the ultra-high frequency. That is, the first antenna 100, located in the space where the plasma 1 is generated, may receive the ultra-high frequency and transmit it to the space where the plasma 1 is generated, and the first antenna 100 may again receive the ultra-high frequency that has passed through the plasma 1.

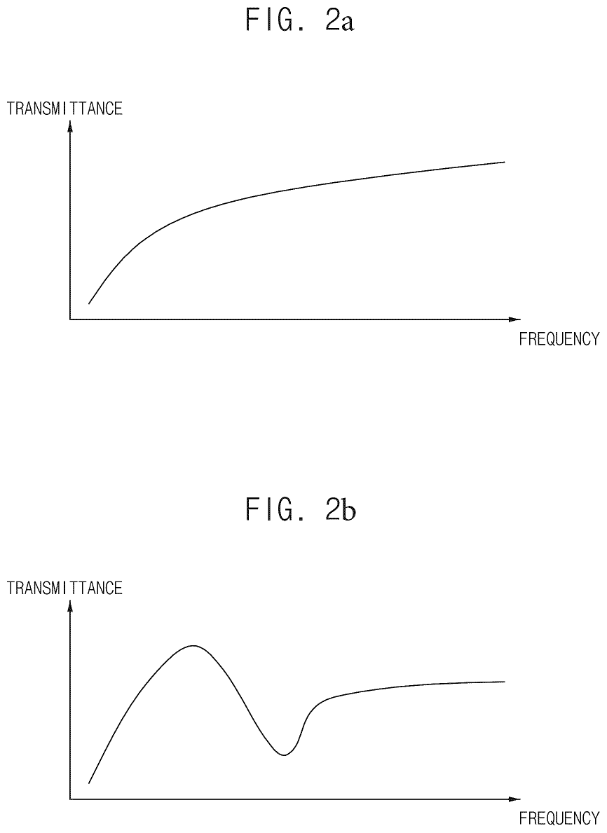

FIGS. 2a and 2b are graphs showing the change in transmittance when plasma is measured through the ultra-high frequency diagnostic device of FIG. 1.

As shown in FIG. 2a, when plasma is not generated in the plasma generation space, the transmittance of the provided ultra-high frequency signal increases proportionally as the frequency of the signal increases.

However, as shown in FIG. 2b, when plasma is generated, the transmittance of the signal decreases sharply despite increase of the frequency of the ultra-high frequency signal. Thus, the signal processing part 600 may obtain information on whether plasma is generated and particular generation pattern of the plasma 1 based on information on the transmittance of the ultra-high frequency signal.

Meanwhile, referring again to FIG. 1, degree of change in the transmittance according to the ultra-high frequency signal may vary according to a spacing distance S1 of the pair of antennas 100 and 200.

That is, since the ultra-high frequency signal transmitted through the first transceiving portion 112 of the first antenna 100 is received by the second transceiving portion 212 of the second antenna 200 after passing through the spacing distance S1, if the spacing distance S1 varies, a signal showing the degree of change in the obtained transmittance may also vary.

Therefore, by varying the spacing distance S1, information on plasma generation according to depth may be obtained in the state where the plasma 1 is generated. In particular, in this embodiment, since the antennas 100 and 200 are formed to be located or detachable in the plasma generation space, the spacing distance S1 may be also varied in various ways, allowing acquisition of diverse information on the plasma

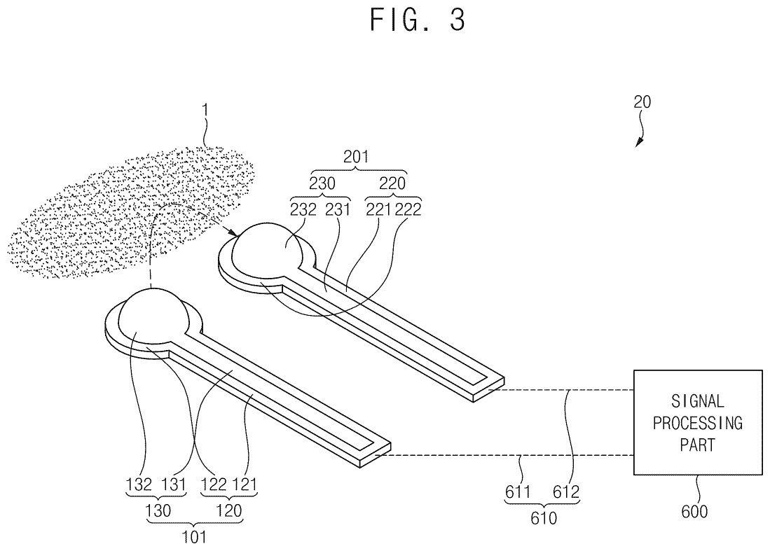

FIG. 3 is a schematic diagram showing a thin-film ultra-high frequency diagnostic device according to another embodiment of the present invention.

The ultra-high frequency diagnostic device 20 according to this embodiment is the same as the ultra-high frequency diagnostic device described with reference to FIG. 1, except that shapes of the first and second electrode units 130 and 230 are different. Thus, the same reference numerals are used for the same components, and redundant explanations are omitted.

That is, referring to FIG. 3, in the case of the ultra-high frequency diagnostic device 20 according to this embodiment, a first transceiving portion 132 of the first electrode unit 130 and a second transceiving portion 232 of the second electrode unit 230 are each formed in a hemispherical shape.

In this case, a first signal line 131 extending from the first transceiving portion 132 and a second signal line 231 extending from the second transceiving portion 232 are the same as the first signal line 111 and the second signal line 211 in FIG. 1 described above.

As described above, when the first transceiving portion 132 and the second transceiving portion 232 are formed in a hemispherical shape, the area in contact with the plasma 1 increases. Thus, transmission and reception of the ultra-high frequency may be performed more effectively, and more accurate information may be obtained.

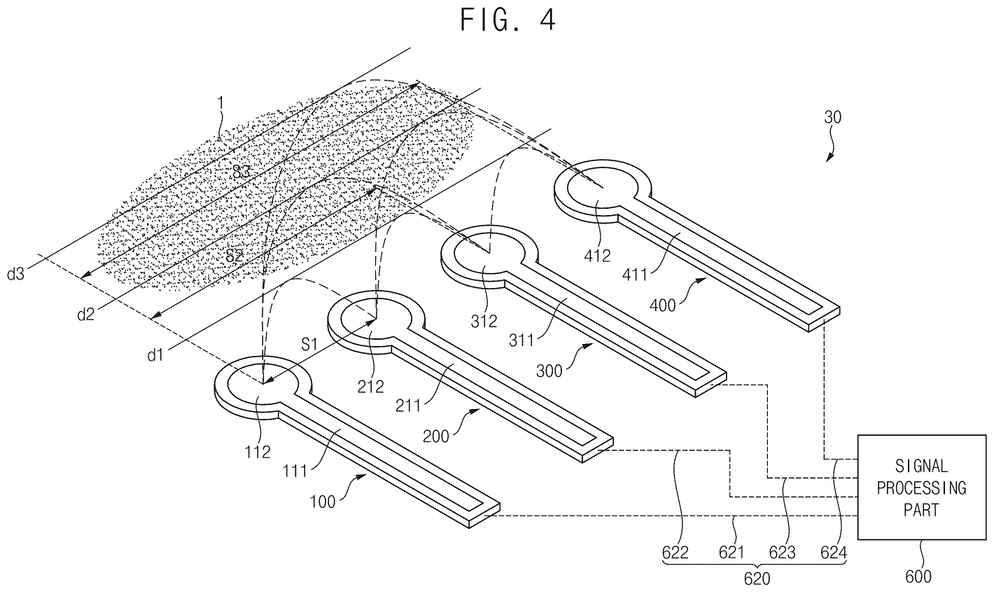

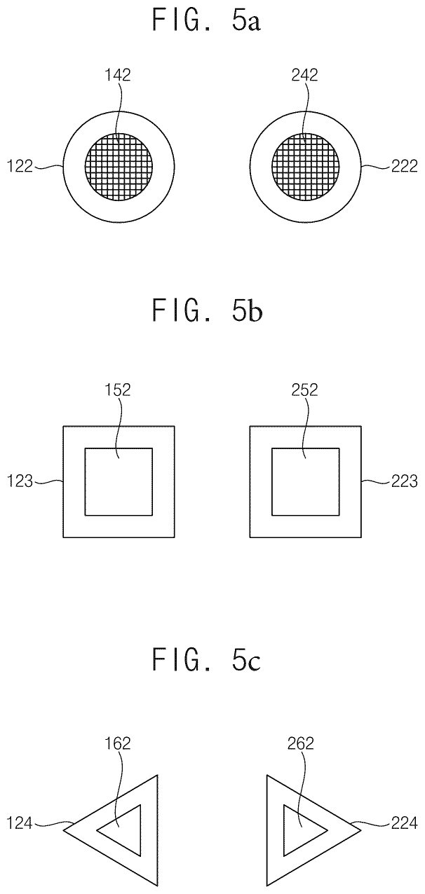

FIG. 4 is a schematic diagram showing a thin-film ultra-high frequency diagnostic device according to another embodiment of the present invention.

The ultra-high frequency diagnostic device 30 according to this embodiment is substantially the same as the ultra-high frequency diagnostic device 10 described with reference to FIG. 1, except that two additional antennas 300 and 400 are arranged. Thus, the same reference numerals are used for the same components, and redundant descriptions are omitted.

Referring to FIG. 4, the ultra-high frequency diagnostic device 30 according to this embodiment further includes third and fourth antennas 300 and 400 in addition to first and second antennas 100 and 200.

In addition, a signal transmission lines 620 included in a signal processing part 600 also further includes third and fourth transmission lines 623 and 624 respectively connected to the third and fourth antennas 300 and 400, in addition to first and second transmission lines 621 and 622 respectively connected to the first and second antennas 100 and 200.

The case of the first to fourth antennas 100, 200 and 300, and 400 may be arranged at predetermined spacing distances in the space where the plasma 1 is generated, and the spacing distances of these antennas may be variously preset. Alternatively, the spacing distances may be variously varied through attachment and detachment as needed.

For example, the first and second antennas 100 and 200 may be spaced apart from each other by a first spacing distance S1, the first and third antennas 100 and 300 may be spaced apart from each other by a second spacing distance S2, and the first and fourth antennas 100 and 400 may be spaced apart from each other by a third spacing distance S3.

In addition, each of the first to fourth antennas 100, 200 and 300, and 400 may serve as a transmitter or a receiver. That is, each of the first to fourth transceiving portions 112, 212, 312, and 412 may transmit or receive ultra-high frequency, and transmission and reception of ultra-high frequency may be performed through a combination of a pair of transceiving portions.

Furthermore, as the spacing distance between the transceiving portions combined with each other increases, information may be obtained at a deeper depth of the generated plasma 1.

For example, the first and second transceiving portions 112 and 212 spaced apart from each other by the first spacing distance S1 may transmit and receive ultra-high frequency with a pair thereof so that information on the first depth d1 of the plasma 1 may be obtained. In addition, the first and third transceiving portions 112 and 312 spaced apart from each other by the second spacing distance S2 may transmit and receive ultra-high frequency with a pair thereof so that information on the second depth d2 of the plasma 1 may be obtained. Furthermore, the first and fourth transceiving portions 112 and 412 spaced apart from each other by the third spacing distance S3 may transmit and receive ultra-high frequency with a pair thereof so that information on the third depth d3 of the plasma 1 may be obtained.

Furthermore, in addition to transmitting and receiving ultra-high frequency between transceiving portions spaced far apart from each other as described above, ultra-high frequency may be also transmitted and received between adjacent transceiving portions, for example, between the third and fourth transceiving portions 312 and 412. Accordingly, by transmitting and receiving ultra-high frequency at various separation spacing distances, information on the state of the plasma 1 may be obtained according to various depths, and eventually, three-dimensional generation information of the plasma 1 generated in the space may be obtained.

Meanwhile, as described above, since locations of the first to fourth antennas 100, 200 and 300, and 400 may be each varied, it is possible to obtain more diverse information for the plasma state through position variation.

Furthermore, although FIG. 4 illustrates the arrangement of four different antennas in one space, it is possible to arrange three antennas, and four or more antennas may be also arranged.

As described above, by variously designing the arrangement of at least two antennas, it is possible to variously analyze generation state, generation range, and generation form of the plasma in the space where the plasma is generated.

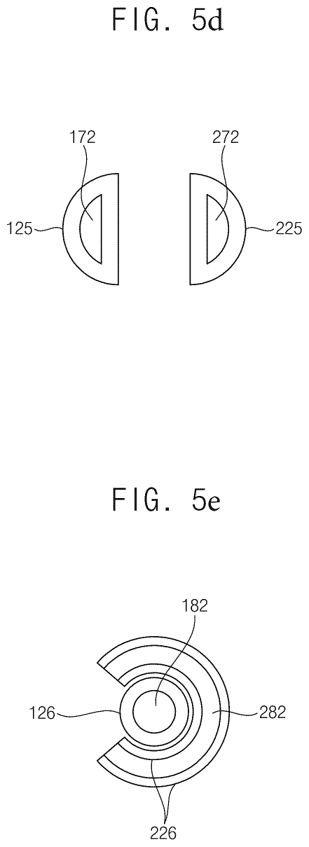

FIGS. 5a to 5e are schematic diagrams showing examples of shapes of transceiving portions and end portions in the ultra-high frequency diagnostic devices of FIGS. 1, 3, and 4.

In FIGS. 1 and 4, the transceiving portions 112, 212, 312, and 412 of each antenna are illustrated as having a circular thin-film shape, but the shapes of the transceiving portions are not limited thereto.

That is, as shown in FIG. 5a, the transceiving portions 142 and 242 may have a circular thin-film shape and may include a mesh structure. Thus, they may be configured in the form of a mesh electrode to perform transmission and reception of ultra-high frequency signals. As described above, since the transceiving portions 142 and 242 are formed on the base substrate, end portions 122 and 222, which are dielectric materials, are exposed to outside along edges of the transceiving portions 142 and 242.

In addition, as shown in FIGS. 5b to 5d, the transceiving portions 152, 252, 162, 262, 172, and 272 may each have a rectangular thin-film shape, a triangular thin-film shape, or a semicircular thin-film shape, and although not illustrated, they may have various planar shapes such as a polygonal thin-film shape or a fan-shaped thin-film shape. End portions 123, 223, 124, 224, 125, and 225, which are dielectric materials, are exposed along outer edges of the transceiving portions.

Furthermore, as shown in FIG. 5e, when one transceiving portion 182 has a circular thin-film shape and an end portion 126, which is a dielectric material, is exposed to outside from outer edge of the transceiving portion 182, another transceiving portion 282 may have a hollow thin-film shape surrounding an outer curved surface of the transceiving portion 182. In this case, an end portion 226, which is a dielectric material, is also exposed to the outside from the edge of the transceiving portion 282.

As described above, the transceiving portions may be formed in various shapes, and by spacing adjacent transceiving portions at predetermined spacing distances, transmission and reception of ultra-high frequency may be performed, and the plasma in the corresponding space may be analyzed.

Furthermore, although FIGS. 5a to 5e illustrate arrangement of transceiving portions in the case where a pair of antennas are provided, the transceiving portions may be arranged within an obvious range that may be inferred from this even when three or more antennas are provided.

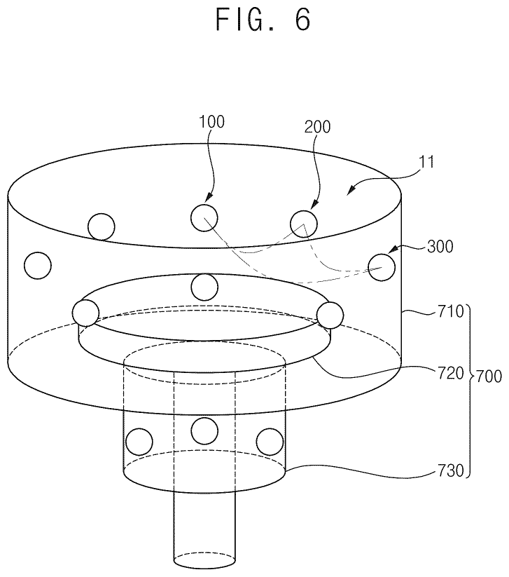

FIG. 6 is a perspective view showing a state in which a plasma diagnostic module including the ultra-high frequency diagnostic devices of FIGS. 1, 3, and 4 is attached to a chamber part.

Referring to FIG. 6, the ultra-high frequency diagnostic devices 10, 20, and 30 described with reference to FIGS. 1, 3, and 4 may form a plasma diagnostic module 11 while having a predetermined arrangement.

Thus, as shown in FIG. 6, the ultra-high frequency diagnostic devices 10, 20, and 30 may be arranged with a predetermined arrangement inside a chamber part 700 including a chamber 710, a wafer chuck 720, and a connection portion 730. Though such configuration, generation state of plasma generated in the chamber part 700 may be diagnosed.

For example, each of antennas 100, 200, and 300 constituting the plasma diagnostic module 11 may be arranged with a predetermined arrangement on an inner surface of the chamber 710. In this case, for convenience of illustration, only transceiving portions and end portions of each of the antennas 100, 200, and 300 are shown, but it is obvious that the antennas actually include signal lines and base substrates.

In addition, the antennas 100, 200 and 300 may be arranged in a predetermined array on the wafer chuck 720 where a wafer is located to form the plasma diagnostic module 11. Furthermore, they may be arranged in a predetermined array on the connection portion 730 connecting the wafer chuck 720 and the external structure.

In this case, the antennas 100, 200 and 300 may be attached to a surface of each structure. Alternatively, they may be located to face the space with their ends fixed to the surface of each structure.

Thus, when multiple ultra-high frequency diagnostic devices are arranged as a set to form a plasma diagnostic module, by transmitting and receiving ultra-high frequency signals in various combinations between the antennas, it is possible to derive information about the density of the plasma generated in the chamber part 700 in three dimensions.

Therefore, compared to measured results obtained from only one ultra-high frequency diagnostic device located on one inner surface of the chamber part 700, it is possible to derive more accurate information about the plasma state and to obtain information about the three-dimensional plasma state in the chamber part 700. Thus information about the uniformity or accuracy of processes performed in the chamber part 700 may be accurately obtained thereby improving effects of process monitoring.

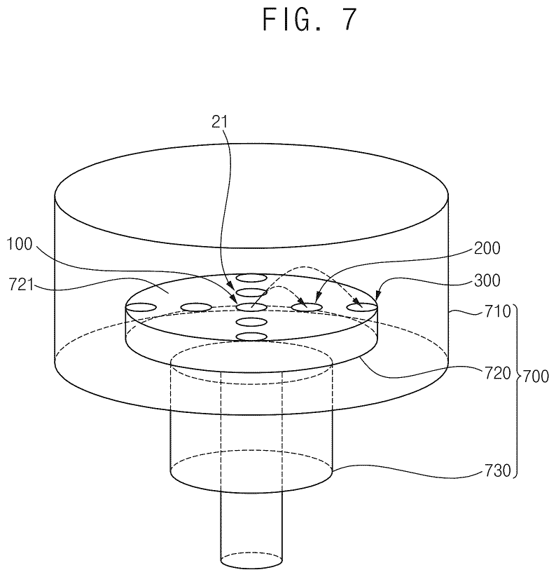

FIG. 7 is a perspective view showing a state in which a plasma diagnostic module including the ultra-high frequency diagnostic devices of FIGS. 1, 3, and 4 is attached to a wafer chuck.

As shown in FIG. 7, the ultra-high frequency diagnostic devices 10, 20, 30 described with reference to FIGS. 1, 3, and 4 may be attached to a surface of a wafer chuck 720 in a predetermined array to form a plasma diagnostic module 21.

Thus, it is possible to perform three-dimensional diagnosis of the plasma generation state around a wafer (not shown) in a state where a semiconductor process is performed on the wafer chuck 720.

In particular, as shown, by placing the first antenna 100 at the center of the wafer chuck 720 and arranging the second and third antennas 200 and 300 outward from the first antenna 100 at predetermined spacing distances, it is possible to diagnose the three-dimensional generation state of the plasma around the wafer. In this case, as shown, the antennas may be arranged in a ‘+’ shape on the surface of the wafer chuck 720, and the arrangement may be variously changed.

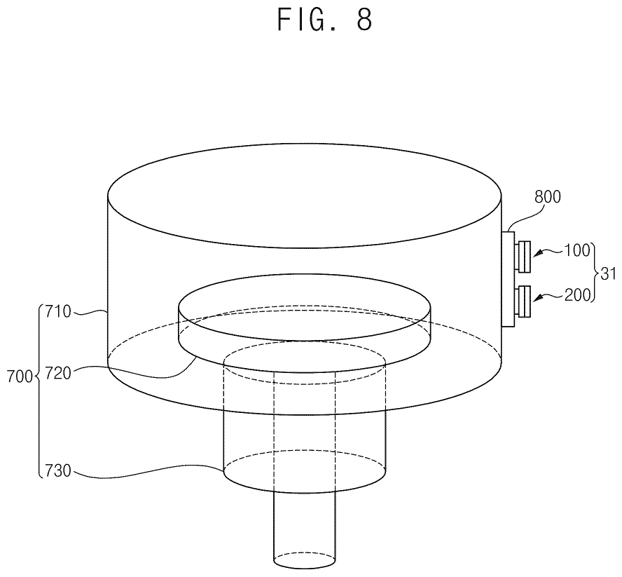

FIG. 8 is a perspective view showing a state in which a plasma diagnostic module including the ultra-high frequency diagnostic device of FIG. 1 is attached to a viewing window of the chamber part.

When plasma is generated in the chamber 710 of the chamber part 700, the plasma diagnostic module 31 may be damaged due to the generation of the plasma.

Therefore, as shown in FIG. 8, a transparent viewing window 800 may be formed at a side of the chamber 710, and the plasma diagnostic module 31 may be located outside the transparent viewing window 800.

Thus, the antennas 100 and 200 of the plasma diagnostic module 31 may diagnose the plasma generated in the chamber 710 through the viewing window 800. In this case, since the ultra-high frequency signals transmitted and received through the antennas 100 and 200 may pass through the transparent viewing window 800, the ultra-high frequency signals may penetrate the plasma through the transceiving portions, thereby performing diagnosis of the plasma.

According to the embodiments of the present invention as described above, unlike conventional embedded or integrated ultra-high frequency diagnostic devices, the antennas may be independently located in a space where plasma is generated to measure the plasma. Thus, they may be located at any position in various spaces where plasma is generated, thereby enabling effective plasma measurement without structural design for embedding the diagnostic device.

In particular, since the antenna is formed of a flexible metal thin film, it is not only easy to manufacture but also may be easily attached and detached to an inner surface of structures with various shapes, and may be also located in a space with its end fixed to the structure, thereby improving convenience in installation or removal.

In addition, a transceiving portion constituting the antenna may be formed in various shapes, not only in a planar shape but also in a three-dimensional shape such as a hemispherical shape thereby allowing control of the signal strength, and may be manufactured in an optimal shape considering various plasma generation or measurement environments.

In addition, by changing a spacing distance between two antennas, it is possible to variably control depth of measured plasma. Furthermore, by arranging three or more antennas at once, it is possible to measure the generated plasma through signal transmission and reception between the antennas at various depths and obtain information about plasma state in three-dimensional space.

In this case, if damage to the ultra-high frequency diagnostic device is anticipated due to the plasma, the plasma generation space and the diagnostic device may be opened with a transparent viewing window through which the ultra-high frequency may pass, thereby diagnosing the plasma with minimizing damage to the diagnostic device.

In particular, the ultra-high frequency diagnostic devices are arranged in multiple to form a plasma diagnostic module, and this plasma diagnostic module is located inside a space where plasma is generated, such as a chamber, or attached to the inner surface of the chamber in a predetermined pattern, thereby enabling the acquisition of three-dimensional information about the plasma generation state, thereby obtaining more accurate and detailed information about the plasma generation state.

Furthermore, the plasma diagnostic module may be attached to a wafer chuck, thereby allowing accurate monitoring of the plasma state around the wafer when a plasma process on the semiconductor wafer is performed.

Meanwhile, the following describes other embodiments of the thin-film ultra-high frequency diagnostic device, in which a base substrate has a relatively larger area than an electrode unit.

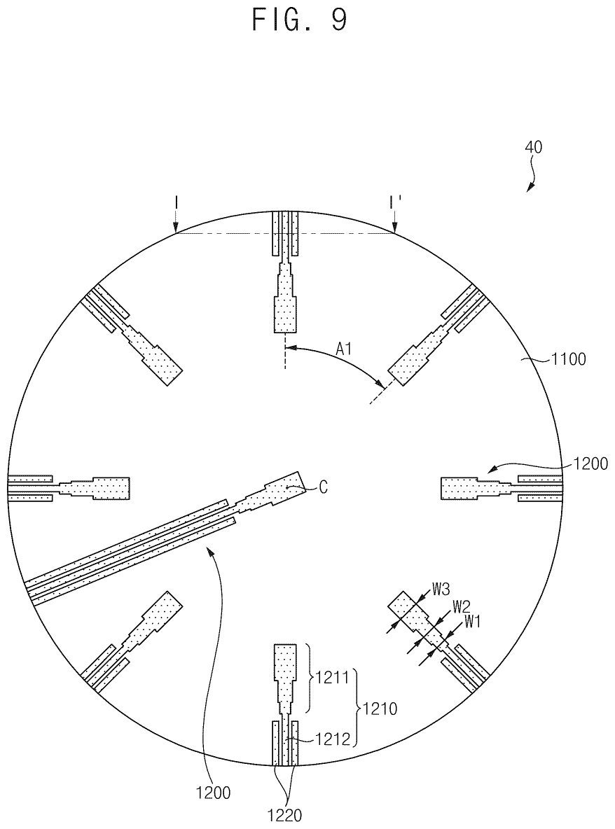

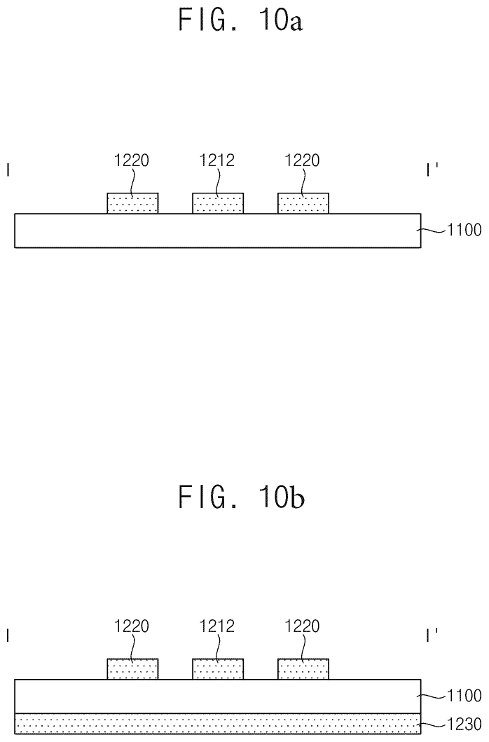

FIG. 9 is a plan view showing a thin-film ultra-high frequency diagnostic device according to another embodiment of the present invention. FIG. 10a is an embodiment of a cross-sectional view taken along line I-I′ of FIG. 9, and FIG. 10b is another embodiment of a cross-sectional view taken along line I-I′ of FIG. 9.

First, referring to FIGS. 9 and 10a, the ultra-high frequency diagnostic device 40 according to this embodiment includes a base substrate 1100 and an electrode unit 1200.

The ultra-high frequency diagnostic device 40 is located in a space where plasma is generated to diagnose the plasma, and the space where the ultra-high frequency diagnostic device 40 is located is not limited.

The base substrate 1100 may have a circular plate shape as shown, and the base substrate 1100 having such a circular plate may be located on a wafer for a semiconductor processing, for example, to diagnose the plasma generated when a semiconductor process is performed on the wafer.

In this case, the base substrate 1100 may be formed as a thin film, for example, a flexible dielectric substrate such as polyimide (PI) as previously described. Thus, it may generate a predetermined electrical induction effect on an electrical signal transmitted through the electrode unit 1200.

The base substrate 1100 may be directly attached and detached to the wafer. The base substrate 1100 may be also easily attached to an outer surface of curved shapes or shapes with predetermined bends, in addition to flat structures like the wafer.

The electrode unit 1200 is formed on the base substrate (1100) and may be formed at a plurality of positions on the base substrate 1100 as shown.

In this case, to diagnose plasma generation in a specific space through the ultra-high frequency diagnostic device 40, the electrode unit 1200 may be located to form an overall uniform spacing distance on the base substrate 1100. Thus, as shown in FIG. 9, on the base substrate 1100 having a circular plate shape, the electrode unit 1200 may be formed at regular spacing distances A1 along the circumference of the base substrate 1100. Furthermore, to diagnose plasma generation at the center C of the base substrate 1100, a specific electrode unit 1200 may be formed to face the center C of the base substrate 1100.

Specifically, the electrode unit 1200 includes a signal line portion 1210 and a ground line 1220, and the signal line portion 1210 includes a transceiving portion 1211 and a signal line 1212.

In the embodiments described with reference to FIGS. 1 to 8, the electrode unit was defined to include the transceiving portion and the signal line, but in the following embodiments including the present embodiment, the ground line 1220 is additionally formed, so the signal line portion 1210 is defined to include the transceiving portion 1210 and the signal line 1212, and the electrode unit 1200 is described to further include the ground line 1220 in addition to the signal line portion 1210.

The signal line 1212 is formed on the base substrate 1100 to extend in a direction, and the transceiving portion 1211 is further extended from the end of the signal line 1212 in the direction in which the signal line 1212 extends.

In this case, although not shown, the signal line 1212 is connected to an external signal processing part (see 600 in FIG. 1) through an individual connection wire to receive an ultra-high frequency signal from the signal processing part or to transmit a detected signal to the signal processing part.

At this time, the extension direction of the signal line 1212 may be a direction from an outer curved surface of the base substrate 1100 toward the center C. Through such configuration, the transceiving portion 1211 may be formed with a uniform spacing distance A1 across the entire base substrate 1100.

The transceiving portion 1211 is further extended from the signal line 1212, thereby being located closer to the center C of the base substrate 1100. However, the extension length of the transceiving portion 1211 may be designed in various ways, considering the radius or width of the base substrate 1100. Also, as shown in FIG. 9, a specific transceiving portion may be formed to extend to the center C for signal detection at the center C of the base substrate 1100.

The width of the transceiving portion 1211, as shown, may increase stepwise as the transceiving portion 1211 extends from the signal line 1212. That is, as shown in FIG. 9, the transceiving portion 1211 is formed with a first width W1 for a predetermined length at the position where the transceiving portion 1211 is connected to the signal line 1212, then formed with a second width W2 larger than the first width W1 for a predetermined length as the spacing distance away from the signal line 1212 increases, and then formed with a third width W3 larger than the second width W2 for a predetermined length at its end.

As described above, the width of the transceiving portion 1211 increases stepwise as a spacing distance away from the signal line 1212 increases, and the width W3 at the position, where the plasma signal is detected, is greatest.

Through such configuration, the area of the portion detecting the plasma signal may be maximized, thereby improving the detection accuracy and the strength of the detected signal of the plasma signal.

The transceiving portion 1211 may provide the ultra-high frequency signal transmitted from the signal line 1212 to the plasma generation area, or receive the signal reflected by the plasma in the plasma generation area, and the received signal is provided to the signal line 1212. Thus, the signal processing part eventually detects the plasma generation at the corresponding position.

Of course, in addition to such active detection, the transceiving portion 1211 may also perform passive detection. The transceiving portion 1211 may simply detect the plasma signal generated in the plasma generation area and may transmit it to the signal line 1212, and the signal processing part may detect the plasma generation at the corresponding position.

Meanwhile, the transceiving portion 1211 and the signal line 1212 as described above may be formed of a flexible metal thin film.

The ground line 1220 is formed adjacent to the signal line 1212 and extends along the extension direction of the signal line 1212.

In particular, as shown in FIGS. 9 and 10a, the ground line 1220 may be formed as a pair on both sides of the signal line 1212, with a predetermined spacing distance from the signal line 1212. Also, the extension length of the ground line 1220 may be formed to be substantially the same as the extension length of the signal line 1212. Thus, the ground line 1220 is not separately formed in the area where the transceiving portion 1211 is formed.

As described above, as the ground line 1220 is formed as a pair on both sides of the signal line 1212, coupling for the ultra-high frequency signal is improved, thereby enhancing the strength of the measured signal and enabling more accurate signal detection.

In this case, although not shown, the ground line 1220 is grounded through an individual connection wire to the outside of the base substrate 1100.

Also, the ground line 1220 is formed on the same surface of the base substrate 1100 where the signal line 1212 is formed, either on the upper or lower surface of the base substrate 1100, and may be formed of a flexible metal thin film like the signal line 1212.

Eventually, the ground line 1220, as well as the signal line 1212 and the transceiving portion 1211, may be formed at once through patterning by the same process, so that a forming process of the electrode unit 1200 in the ultra-high frequency diagnostic device 40 of FIG. 9 may be greatly simplified.

Alternatively, as shown in FIG. 10b, the electrode unit 1200 may further include a ground portion 1230.

The ground portion 1230 is formed, for example, on the lower surface of the base substrate 1100, on the opposite surface to the surface where the signal line portion 1210 and the ground line 1220 are formed.

Although not shown, the ground portion 1230 is also grounded through an individual connection wire to the outside of the base substrate 1100.

As described above, as the ground portion 1230 is additionally formed, the sensitivity of the signal detected through the electrode unit 1200 is improved, thereby enhancing the accuracy of the measurement results.

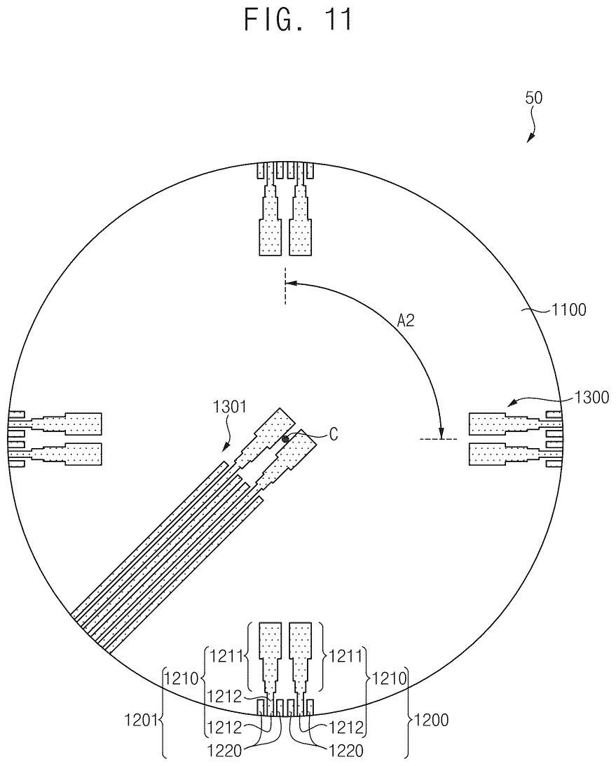

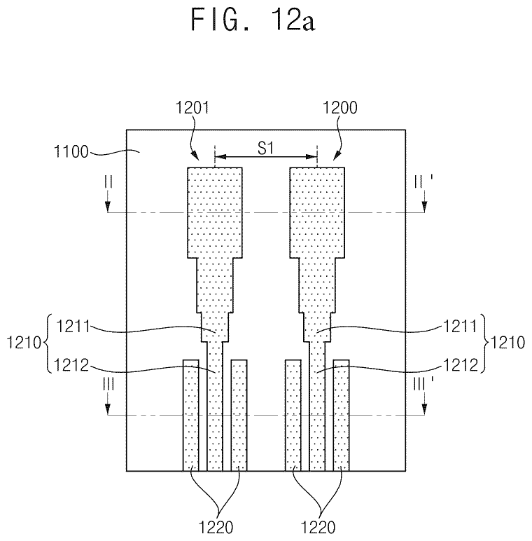

FIG. 11 is a plan view showing another embodiment of the thin-film ultra-high frequency diagnostic device according to the present invention.

The ultra-high frequency diagnostic device 50 according to the present embodiment, except that a pair of electrode units 1300 are arranged adjacent to each other, is substantially the same as the ultra-high frequency diagnostic device 40 described with reference to FIGS. 9 to 10b. Thus, the same reference numerals are used for the same components, and redundant descriptions are omitted.

Referring to FIG. 11, in the ultra-high frequency diagnostic device 50, a pair of first electrode unit 1200 and second electrode unit 1201 are arranged adjacent to each other on the base substrate 1100.

In this case, each of the first and second electrode units 1200, 1201 is substantially the same as the electrode unit 1200 described with reference to FIG. 9.

Also, in this embodiment, as the pair of first and second electrode units 1200 and 1201 are formed adjacent to each other, a spacing distance A2 by which the electrode units 1300 are arranged may be increased compared to a spacing distance A1 by which the electrode units 1200 are arranged in FIG. 9. However, this is simple design change and may be designed in various ways considering the area or the radius of the base substrate 1100.

Furthermore, in this embodiment, to detect plasma generation at the center C of the base substrate 1100, a specific electrode unit 1301 may be formed to extend to the center C of the base substrate 1100. In this case, other electrode units 1300 are formed with uniform spacing distances A2 along the outer curved surface of the base substrate 1100, as in FIG. 9.

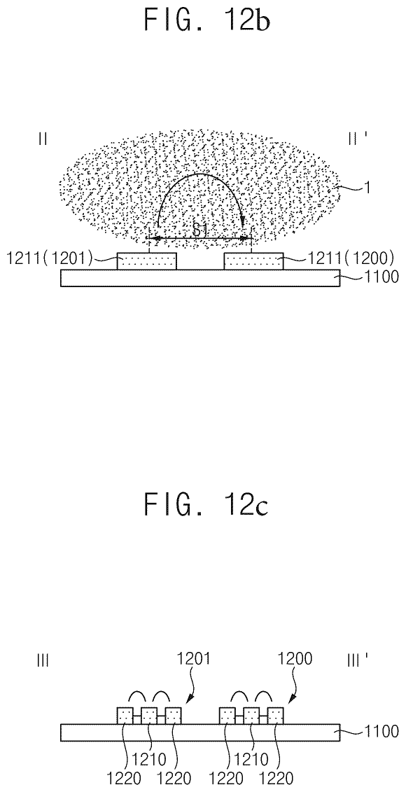

Hereinafter, signal detection in the case where the pair of first and second electrode units 1200, 1201 are provided will be described with reference to FIGS. 12a to 12c.

FIG. 12a is an enlarged plan view showing a pair of electrode units in the ultra-high frequency diagnostic device of FIG. 11, FIG. 12b is a cross-sectional view taken along line II-II′ of FIG. 12a, and FIG. 12c is a cross-sectional view taken along line III-III′ of FIG. 12a.

Referring to FIGS. 12a and 12b, in the electrode unit 1300, an end of the transceiving portion 1211 of the first electrode unit 1200 and an end of the transceiving portion 1211 of the second electrode unit 1201 are spaced apart from each other by a predetermined spacing distance S1.

Thus, for example, when an ultra-high frequency signal is transmitted through the transceiving portion 1211 of the second electrode unit 1201, the ultra-high frequency signal passes through the plasma 1 and is received through the transceiving portion 1211 of the first electrode unit 1200, thereby performing detection of the plasma 1.

At this time, the ultra-high frequency signal is provided through the signal line 1212 of the second electrode unit 1201, and the detected signal is provided to an external signal processing part through the signal line 1212 of the first electrode unit 1200.

Alternatively, the ultra-high frequency signal may be transmitted through the first electrode unit 1200 and the signal passing through the plasma 1 may be received through the second electrode unit 1201.

Meanwhile, as described above, by varying the spacing distance S1 between the transceiving portions of the first and second electrode units 1200 and 1201, plasma generation information according to depth may be obtained, thereby acquiring more diverse information about the plasma in a specific space.

Also, referring to FIGS. 12a and 12c, in this embodiment, in each of the first and second electrode units 1200 and 1201, a pair of the ground lines 1220 are formed on the same surface on both sides of the signal line 1212.

Thus, as shown, the coupling efficiency of the signal between the ground line 1220 and the signal line 1212 may be improved, thereby enabling more sensitive signal detection and improving the accuracy of plasma detection.

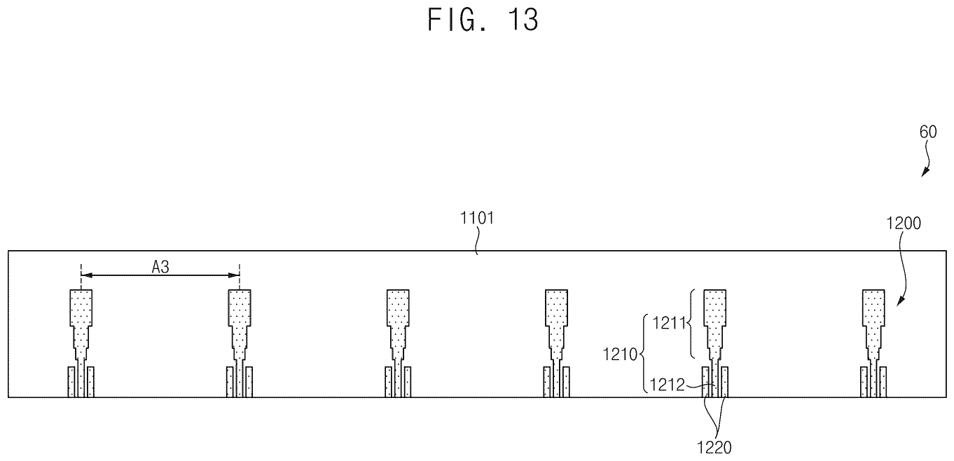

FIG. 13 is a plan view showing a thin-film ultra-high frequency diagnostic device according to another embodiment of the present invention.

The ultra-high frequency diagnostic device 60 according to this embodiment is substantially the same as the ultra-high frequency diagnostic device 40 described with reference to FIG. 9, except for the shape of the base substrate 1101 and the arrangement of the electrode unit 1200. Thus, the same reference numerals are used for the same components and redundant descriptions are omitted.

Referring to FIG. 13, in the ultra-high frequency diagnostic device 60 according to this embodiment, the base substrate 1101 may have a rectangular plate shape extending in a direction. Accordingly, the electrode unit 1200 formed on the base substrate 1101 may be also uniformly formed along the extension direction of the base substrate 1101 with a predetermined spacing distance A3.

In this case, the configuration of each electrode unit 1200 is as described above. Although FIG. 13 illustrates that the electrode units 1200 are arranged at a predetermined spacing distance A3 in a direction, the rows in which the electrode units 1200 are arranged may be two or more, and may be variable depending on the shape of the base substrate 1101.

In particular, the base substrate 1101 as shown in FIG. 13 may be formed on a panel for display in the process of manufacturing the panel, for example, to perform detection of plasma in the panel manufacturing process.

In this case, the base substrate 1101 may be a flexible dielectric substrate, or alternatively, the panel may be used for the base substrate 1101. That is, the electrode unit 1200 may be directly formed on the panel to perform detection of the plasma.

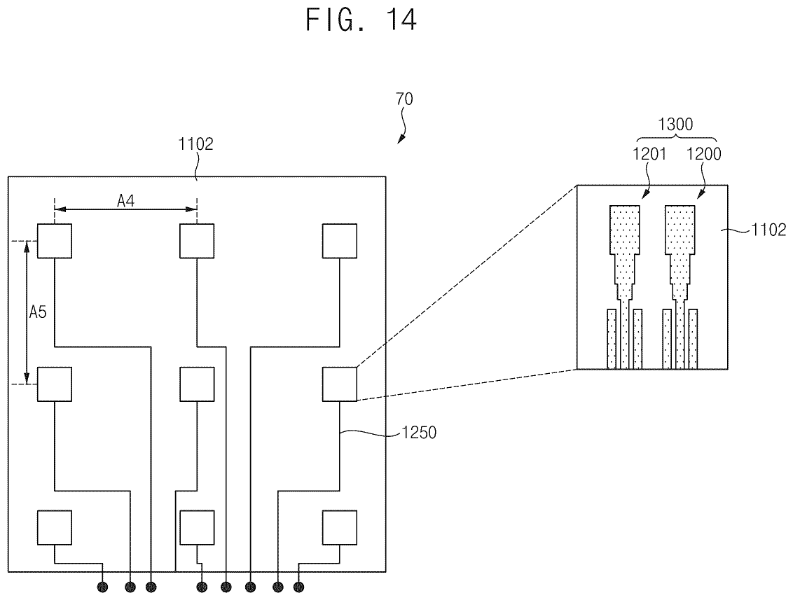

FIG. 14 is a plan view showing a thin-film ultra-high frequency diagnostic device according to another embodiment of the present invention.

The ultra-high frequency diagnostic device 70 according to this embodiment is substantially the same as the ultra-high frequency diagnostic device 50 described with reference to FIG. 11, except for the shape of the base substrate 1102 and the arrangement of the electrode unit 1300. Thus, the same reference numerals are used for the same components and redundant descriptions are omitted.

Referring to FIG. 14, in the ultra-high frequency diagnostic device 70 according to this embodiment, the base substrate 1102 may have a rectangular or a square plate shape with a predetermined area. Accordingly, the electrode unit 1300 formed on the base substrate 1102 may be also uniformly arranged on the base substrate 1102 with a first spacing distance A4 in the first direction and a second spacing distance A5 in the second direction.

In this case, a pair of electrode units 1200 and 1202 are arranged adjacent to each other as in the electrode unit 1300 of FIG. 11 described above.

However, in this case, since the electrode unit 1300 is not arranged only at the edge of the base substrate 1102, the connection wiring 1250 may extend to the position where the electrode unit 1300 is arranged, and the connection wiring 1250 may be electrically connected to the signal processing part located outside the base substrate 1102 as described above.

Meanwhile, although FIG. 14 illustrates that the electrode units 1300 are uniformly arranged at nine positions in total on the base substrate 1102, the arrangement of the electrode units 1300 may vary depending on the shape of the base substrate 1102.

Furthermore, the base substrate 1102 as shown in FIG. 14 may be also formed on a panel for display in the process of manufacturing the panel, for example, to perform detection of plasma in the panel manufacturing process. Alternatively, the base substrate 1102 may be omitted and the electrode unit 1300 may be formed on the panel to perform detection of the plasma.

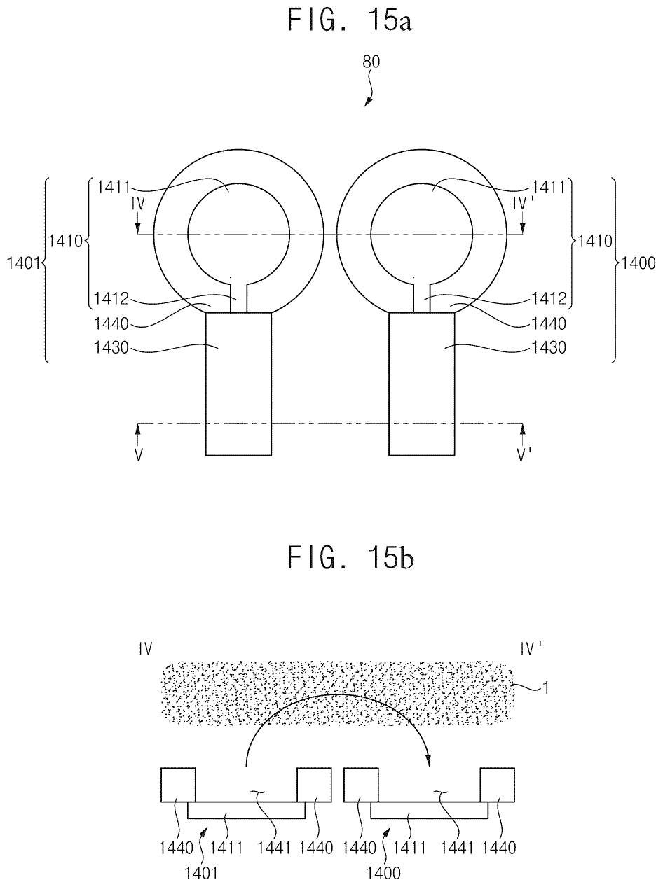

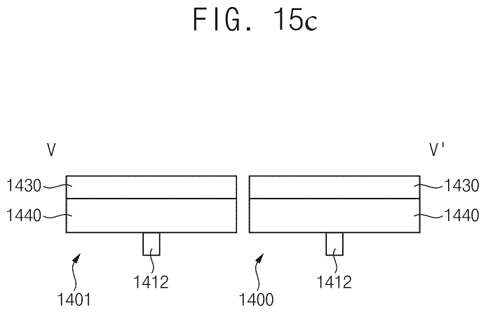

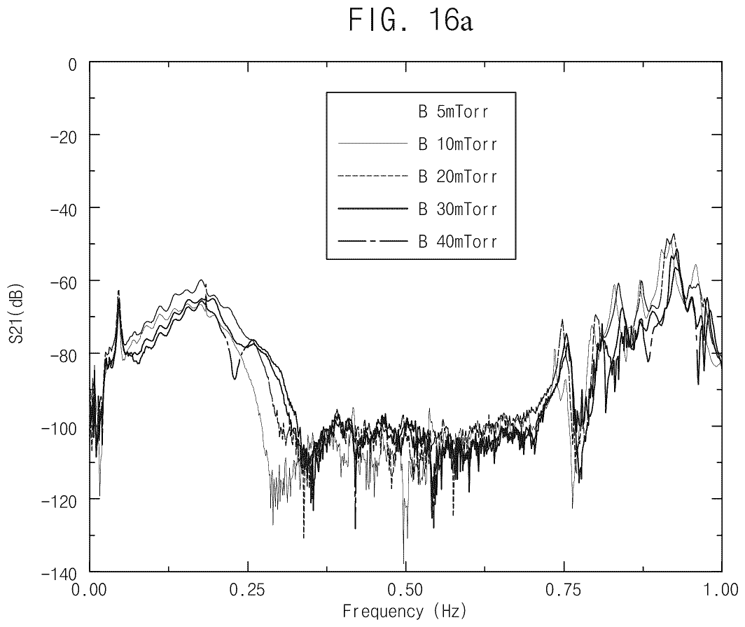

FIG. 15a is a plan view showing an electrode unit of a thin-film ultra-high frequency diagnostic device according to another embodiment of the present invention, FIG. 15b is a cross-sectional view taken along line IV-IV′ of FIG. 15a, and FIG. 15c is a cross-sectional view taken along line V-V′ of FIG. 15a.

Referring to FIGS. 15a to 15c, the ultra-high frequency diagnostic device 80 according to this embodiment includes first and second electrode units 1400 and 1401 formed as a pair.

In this case, the first and second electrode units 1400 and 1401 are spaced apart by a predetermined spacing distance and formed as a pair adjacent to each other as in the electrode unit 1300 of FIG. 11, and configurations of the first and second electrode units 1400 and 1401 are the same. Therefore, only the first electrode unit 1400 will be described in detail.

Furthermore, although FIG. 15a illustrates that a pair of electrode units 1400 and 1401 are formed adjacent to each other, three or more electrode units may be arranged adjacent to each other to form the ultra-high frequency diagnostic device 80.

Particularly, the first electrode unit 1400 includes a signal line portion 1410, a dielectric portion 1440, and a ground portion 1430.

The dielectric portion 1440 is formed to extend in a direction and may be formed with a relatively large area, for example, in a circular shape, in the portion where the signal line portion 1410 is formed.

The dielectric portion 1440 includes a flexible dielectric, for example, polyimide (PI). Thus, it may generate a certain electrical induction effect on electrical signals such as an ultra-high frequency signal transmitted through the signal line portion 1410.

The signal line portion 1410 includes a transceiving portion 1411 and a signal line 1412.

The transceiving portion 1411 is formed on a surface of the dielectric portion 1440, for example, on a lower surface, and is formed in a circular shape with a smaller area than the area where the dielectric portion 1440 is formed. That is, the radius of the transceiving portion 1411 is smaller than the radius of the dielectric portion 1440.

When the upper surface of the dielectric portion 1440 is defined as the surface facing the plasma 1 and when the lower surface of the dielectric portion 1440 is defined as the surface opposite to the upper surface, the transceiving portion 1411 is formed on the surface opposite to the surface facing the plasma 1.

Thus, for signal detection of the plasma 1, an opening 1441 is formed in a center of the dielectric portion 1440, and the transceiving portion 1411 is exposed to the plasma 1 through the opening 1441.

The signal line 1412 extends from an end of the transceiving portion 1411 along the direction in which the dielectric portion 1440 extends, and the width of the signal line 1412 is smaller than the width of the dielectric portion 1440.

In this case, since the signal line 1412 extends from the transceiving portion 1411, it is formed on the lower surface of the dielectric portion 1440, similar to the transceiving portion 1411.

The signal line 1412 transmits an ultra-high frequency signal or a detection signal and, although not shown, is electrically connected to an external signal processing part.

The ground portion 1430 is formed on the upper surface of the dielectric portion 1440, that is, on the opposite surface to the surface where the signal line 1412 is formed, and is formed over the entire dielectric portion 1440 along the area where the signal line 1412 extends, except for the area where the transceiving portion 1411 is formed.

That is, as shown, the ground portion 1430 is formed on the upper surface of the dielectric portion 1440, which extends in a straight line, except for the circular dielectric portion 1440.

Although not shown, the ground portion 1430 is grounded to outside through an individual connection wire.

In this embodiment, the dielectric portion 1440 is a flexible dielectric substrate as previously described, and both the signal line portion 1410 and the ground portion 1430 may be formed of a flexible metal thin film.

Plasma detection in the ultra-high frequency diagnostic device 80 is similar to the plasma detection in the ultra-high frequency diagnostic device 50 described with reference to FIGS. 12a to 12c.

For example, in the second electrode unit 1401, when an ultra-high frequency signal is transmitted through the transceiving portion 1411, the ultra-high frequency signal passes through the plasma 1 and is received through the transceiving portion 1411 of the first electrode unit 1400, thereby performing detection of the plasma 1.

At this time, the ultra-high frequency signal is provided through the signal line 1412 of the second electrode unit 1401, and the detected signal is provided to an external signal processing part through the signal line 1412 of the first electrode unit 1400.

Alternatively, the ultra-high frequency signal may be transmitted through the first electrode unit 1400, and the signal passing through the plasma 1 may be received through the second electrode unit 1401.

Meanwhile, as described above, by varying the spacing distance between the transceiving portions of the first and second electrode units 1400 and 1401, plasma generation information according to depth may be obtained, thereby acquiring more diverse plasma information in a specific space.

In particular, in this embodiment, since the transceiving portion 1411 is exposed to the plasma generation space through the opening 1441 formed in the dielectric portion 1440, the sensitivity of transmitting and receiving the ultra-high frequency signal is improved, thereby enabling more accurate plasma detection.

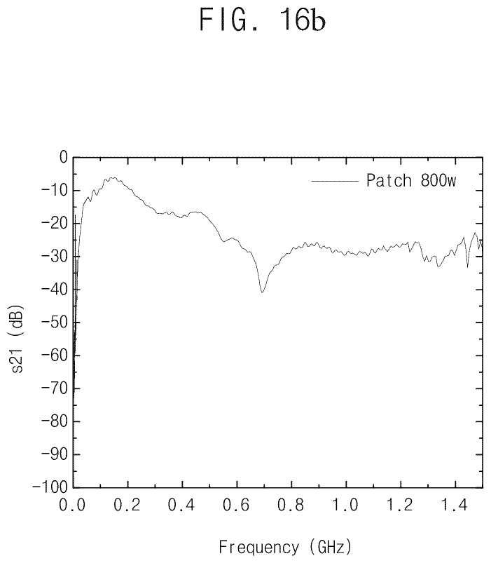

FIG. 16a is a graph showing a transmission spectrum of a diagnostic result using a conventional ultra-high frequency diagnostic device, and FIG. 16b is a graph showing a transmission spectrum of a diagnostic result using the ultra-high frequency diagnostic device of FIG. 15a.

FIG. 16a is a graph showing the transmission spectrum of the detection result of plasma generation using the conventional ultra-high frequency diagnostic device, in which, for example, each of a pair of electrode units has a signal line portion formed on an upper surface and a ground portion formed on a lower surface based on the dielectric portion.

In contrast, FIG. 16b is a graph showing the transmission spectrum of the detection result of plasma generation using the ultra-high frequency diagnostic device 80 having the same structure as illustrated in FIG. 15a.

When comparing FIGS. 16a and 16b, it may be confirmed that the intensity of the detected transmission spectrum signal relatively increases in the ultra-high frequency diagnostic device 80 having the structure of FIG. 15a, thereby confirming that the sensitivity of plasma detection through the ultra-high frequency diagnostic device 80 increases, thereby enabling more accurate detection signals.

According to the embodiments of the present invention as described above, unlike the conventional embedded or integrated plasma diagnostic device, the ultra-high frequency diagnostic device may measure plasma in the space where plasma is generated, and may be located at any position in various spaces where plasma is generated, thereby enabling effective plasma measurement without structural design for embedding the diagnostic device.

In particular, the ultra-high frequency diagnostic device has an electrode unit formed only on one surface of the dielectric base substrate, thereby simplifying the manufacturing process of the electrode unit and enabling mass production.

In addition, the base substrate may be manufactured in various shapes such as a circular plate shape like a wafer, a longitudinal plate shape, and may be easily located in a detachable form at a location where plasma measurement is required, thereby improving convenience of installation and removal.

Furthermore, the base substrate may be directly used as a structure such as a wafer or a display panel, thereby enabling easy plasma measurement by simply attaching and detaching the electrode unit.

Alternatively, by removing the ground portion in the part where the transceiving portion for detecting plasma is formed in the electrode unit, and forming the transceiving portion to be exposed to the outside through the opening, the coupling efficiency of the ultra-high frequency signal to the plasma may be further improved, thereby enabling more accurate signal measurement.

Furthermore, by forming the electrode unit as a pair or more, the signal passing through the plasma may be measured through transmission and reception of signals, thereby obtaining information on the plasma state in a three-dimensional space by measuring the plasma at various depths.

While the preferred embodiments of the present invention have been described above, those skilled in the art will understand that the present invention may be variously modified and changed without departing from the spirit and scope of the invention as set forth in the claims below.

1. An ultra-high frequency diagnostic device comprising at least one antenna located in a space where plasma is generated,
wherein the antenna includes:
a base substrate; and
an electrode unit formed on the base substrate along a center of the base substrate and exposed to the space where the plasma is generated to transmit and receive an ultra-high frequency signal.

2. The ultra-high frequency diagnostic device of claim 1, wherein
the base substrate is a flexible dielectric substrate, and
the electrode unit is formed of a flexible metal thin-film.

3. The ultra-high frequency diagnostic device of claim 2, wherein the electrode unit includes:
a signal line transmitting and receiving the ultra-high frequency signal with a signal processing part; and
a transceiving portion formed at an end of the signal line and transmitting or receiving the ultra-high frequency signal.

4. The ultra-high frequency diagnostic device of claim 3, wherein the transceiving portion is formed of one of a circular thin film, a semicircular thin film, a mesh-shaped circular thin film, a triangular thin film, a rectangular thin film, and a polygonal thin film.

5. The ultra-high frequency diagnostic device of claim 3, wherein the transceiving portion has a lower surface formed as a thin film, and is formed to protrude in a hemispherical shape on the lower surface.

6. The ultra-high frequency diagnostic device of claim 1, wherein
the at least one antenna includes first and second antennas, and
a transceiving portion of the second antenna is arranged to cover an outside of a transceiving portion of the first antenna.

7. The ultra-high frequency diagnostic device of claim 1, wherein
the at least one antenna includes two antennas,
one of the two antennas transmits the ultra-high frequency signal, and the other receives the ultra-high frequency signal, and
as a distance between the two antennas varies, plasma information according to a depth direction of the plasma is acquired.

8. The ultra-high frequency diagnostic device of claim 7, wherein
the antennas include three or more antennas,
the three or more antennas transmit and receive the ultra-high frequency signal therebetween, and
plasma information according to a depth direction of the plasma is acquired according to a distance between the three or more antennas.

9. The ultra-high frequency diagnostic device of claim 1, wherein the antenna further includes a ground portion formed on the lower surface of the base substrate along a center of the lower surface of the base substrate.

10. The ultra-high frequency diagnostic device of claim 1, wherein
an end of the antenna is fixed to a structure forming the space where the plasma is generated, or
a lower surface of the antenna is attached to a surface of the structure.

11. The ultra-high frequency diagnostic device of claim 1, wherein
a transparent viewing window is formed in the space where the plasma is generated, and
the antenna is exposed to the space where the plasma is generated through the transparent viewing window.

12. An ultra-high frequency diagnostic device comprising:
a base substrate; and
an electrode unit formed on the base substrate,
wherein the electrode unit includes:
a signal line portion including a transceiving portion and a signal line, the transceiving portion being exposed to a space where plasma is generated and detecting a ultra-high frequency signal, the signal line extending from the transceiving portion to deliver a detection signal to an outside; and
a ground line formed on the same surface of the base substrate on which the signal line portion is formed, spaced apart from the signal line portion, and extending along an extension direction of the signal line portion.

13. The ultra-high frequency diagnostic device of claim 12, wherein
the base substrate is a wafer or a panel, and
the electrode unit is directly formed on the base substrate as a flexible metal thin film.

14. The ultra-high frequency diagnostic device of claim 13, wherein the transceiving portion, the signal line portion, and the ground line of the electrode unit are simultaneously formed on the base substrate.

15. The ultra-high frequency diagnostic device of claim 12, wherein the base substrate has one of a circular plate shape, a plate shape extending in a longitudinal direction, a rectangular plate shape, a polygonal plate shape, and a curved surface shape.

16. The ultra-high frequency diagnostic device of claim 12, wherein the transceiving portion is formed such that a width thereof increases as a distance from the signal line portion increases.

17. The ultra-high frequency diagnostic device of claim 12, wherein the electrode unit further includes a ground portion formed on a surface opposite to the surface of the base substrate on which the signal line portion is formed.

18. An ultra-high frequency diagnostic device comprising:
a signal line portion including a transceiving portion and a signal line, the transceiving portion being exposed to a space where plasma is generated and detecting a ultra-high frequency signal, the signal line extending from the transceiving portion to deliver a detection signal to an outside;
a dielectric portion having the signal line portion formed on a lower surface thereof and having an opening formed such that the transceiving portion is exposed to the space where the plasma is generated; and
a ground portion formed on an upper surface of the dielectric portion and along an area where the signal line is formed.

19. The ultra-high frequency diagnostic device of claim 18, wherein the signal line portion and the ground portion are formed of a flexible metal thin-film.

20. The ultra-high frequency diagnostic device of claim 18, wherein
the signal line extends in a longitudinal direction along the lower surface of the dielectric portion, and
the ground portion is formed on an entire upper surface of the dielectric portion.
